(19) United States
(12) Patent Application Publication
(10) Pub. No.: US 2022/0271260 A1
(43) Pub. Date: Aug. 25, 2022

(54) ORGANIC LIGHT EMITTING DEVICE

(71) Applicant: The Regents of the University of Michigan, Ann Arbor, MI (US)

(72) Inventors: Stephen R. FORREST, Ann Arbor, MI (US); Haonan Zhao, Ann Arbor, MI (US)

(21) Appl. No.: 17/581,736

(22) Filed: Jan. 21, 2022

Related U.S. Application Data
(60) Provisional application No. 63/152,472, filed on Feb. 23, 2021.

(51) Int. Cl. H01L 51/52

(52) U.S. Cl. CPC H01L 51/5265; H01L 51/5218

(57) ABSTRACT

An organic light emitting device comprises an emissive layer stack having an anode side and a cathode side, comprising at least one emissive layer comprising an organic emissive material, an anode layer stack comprising at least one conductive layer, a cathode layer stack comprising at least one conductive layer, an anode-side reflector positioned on the anode side of the emissive layer stack, and a cathode-side reflector positioned on the cathode side of the emissive layer stack, wherein the anode-side reflector and the cathode side reflector are configured to form a resonant, electrically pumped cavity for ultrastrong coupling having a quality factor of at least 10. An electrically-pumped organic light emitting device is also disclosed.

### CROSS-REFERENCE TO RELATED APPLICATIONS

This application claims priority to U.S. Provisional Patent Application No. 63/152,472, filed on Feb. 23, 2021, incorporated herein by reference in its entirety.

### STATEMENT REGARDING FEDERALLY SPONSORED RESEARCH OR DEVELOPMENT

This invention was made with government support under DE-SC0017971 awarded by the U.S. Department of Energy. The government has certain rights in the invention.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety. One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)3, which has the following structure:

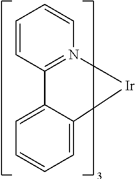

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

One of the most challenging, high value problems facing the field of organic electronics today, and the central challenge facing the implementation of high efficiency white OLED (WOLED) lighting, is to increase the device lifetime of the blue light emitting segments controlled by triplet states. High WOLED efficiencies require utilization of both singlet and triplet excitons, which has involved metalorganic phosphors such as Ir- and Pt-based complexes, and thermally assisted delayed fluorescent (TADF) emitters. All of these materials are characterized by a long-lived triplet-controlled emissive state, with radiative lifetimes extending from ˜1 μs to 100 ms. The principal source of molecular degradation leading to the very short blue triplet emitter OLED lifetime is triplet-triplet and triplet-polaron annihilation (TTA and TPA, respectively) shown in FIG. 1A. Two excitons or an exciton and a polaron collide, promoting one to a high energy, or “hot” excited state, while de-exciting the other exciton to its ground state in an Auger-like process. The top graphs 141 show an exemplary triplet-triplet annihilation, while the bottom graphs 142 show an exemplary triplet-polaron annihilation. D denotes the predissociative state. For blue emission, the exciton energy is 2.6-2.8 eV, resulting in a hot excited state whose energy is 5.2-5.6 eV. If localized on a bond, this energy can destroy the molecule, converting it from an emissive state to a non-radiative recombination center. As more emitting molecules are destroyed, the luminance and efficiency of the WOLED decrease, leading to shorter device operational life. Since the probability of bond-breaking is an exponential function of energy, the destruction of red and green organic emitters is at a markedly reduced rate compared to blue, accounting for the comparatively long lifetimes of OLEDs with red or green emitters.

The degradation model is further understood with reference to FIG. 1B, which shows various defect generation mechanisms and their effect on surrounding excitons. Row 151 of FIG. 1B shows graphical representations of defects generated by a unimolecular process, by triplet-charge interaction, or by triplet-triplet interaction, as well as the rate at which each phenomenon generates defects in row 152. As shown in row 153, each defect 154 causes quenching in the surrounding excitons, which leads to loss and further shortens the device lifetime. As illustrated in Equation 1 below, increasing the triplet density ([T]) in the emissive layer increases the rates of TPA and TTA, which in turn increases the defect generation rate, and is inversely proportional to the Purcell Factor (Fₚ).

$$[ T ] = \frac{G}{{F}_{p} {k}_{R 0} + {k}_{N R} + {k}_{E T} [ D ]} ∝ {F}_{p}^{- 1} \qquad Equation 1$$

For the purposes of Equation 1, k_{R0} is the radiative decay rate in vacuum, k_{NR} is the non-radiative decay rate, k_{ET} is bimolecular quenching rate, and [D] is the defect density. When k_{NR} and k_{ET} are relatively small compared to k_{R0}, Fₚ is roughly inversely proportional to [T]. As shown in Equation 1, as Fₚ increases, triplet density decreases, which causes decreased defect formation, which in turn increases device operational lifetime.

Several strategies have been attempted to mitigate these effects, all involving the reduction of the exciton density in the PHOLED emission zone to reduce annihilation processes. One uses dopant grading, and another is to insert manager molecules into the emission zone to “sink” the excited states before they can engage in TTA or TPA.

### SUMMARY OF THE INVENTION

In one aspect, an organic light emitting device comprises an emissive layer stack having an anode side and a cathode side, comprising at least one emissive layer comprising an organic emissive material, an anode layer stack positioned on the anode side of the emissive layer stack, comprising at least one conductive layer, a cathode layer stack positioned on the cathode side of the emissive layer stack from the anode layer stack, comprising at least one conductive layer, an anode-side reflector positioned on the anode side of the emissive layer stack, and a cathode-side reflector positioned on the cathode side of the emissive layer stack, wherein the anode-side reflector and the cathode side reflector are configured to form a resonant, electrically pumped cavity for ultrastrong coupling, having a quality factor of at least 10.

In one embodiment, the emissive layer comprises a blue organic emissive material. In one embodiment, the emissive layer stack comprises at least one layer comprising an organic emissive material and a host material, and at least one additional layer comprising a host material. In one embodiment, the anode-side reflector is a distributed Bragg reflector (DBR) In one embodiment, the anode-side reflector comprises at least one layer of SiO₂ and at least one layer of SiN_{X}. In one embodiment, the cathode-side reflector comprises a metal. In one embodiment, the cathode-side reflector and the anode side reflector comprise semiconductor materials. In one embodiment, the cathode side reflector comprises at least one layer of Ag and at least one layer of MgF₂. In one embodiment, the emissive layer stack comprises at least an electron transport layer and a hole transport layer. In one embodiment, the cathode layer stack comprises at least one insulating layer. In one embodiment, the cathode layer stack comprises at least one layer of Indium Tin Oxide. In one embodiment, the anode layer stack comprises at least one layer of Indium Tin Oxide.

In one aspect, an electrically-pumped organic light emitting device comprises a resonant, electrically pumped cavity for ultrastrong coupling formed of first and second reflectors, an organic emissive layer positioned in the resonant, electrically pumped cavity, between the first and second reflectors, an anode layer stack positioned between the first reflector and the emissive layer, and a cathode layer stack positioned between the second reflector and the emissive layer.

In one embodiment, the organic emissive layer comprises an organic emissive material and an organic host material. In one embodiment, the organic emissive material is a blue organic emissive material. In one embodiment, at least one of the first and second reflectors is a distributed Bragg reflector. In one embodiment, the first and second reflectors each comprise a plurality of semiconducting sublayers. In one embodiment, the first and second reflectors do not comprise a metal sublayer. In one embodiment, the device further comprises an insulating layer positioned between the cathode layer stack and the emissive layer. In one embodiment, the device further comprises a hole injection layer positioned between the anode layer stack and the emissive layer.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1A shows graphs of molecular dissociation kinetics due to triplet-triplet and triplet-polaron annihilation;

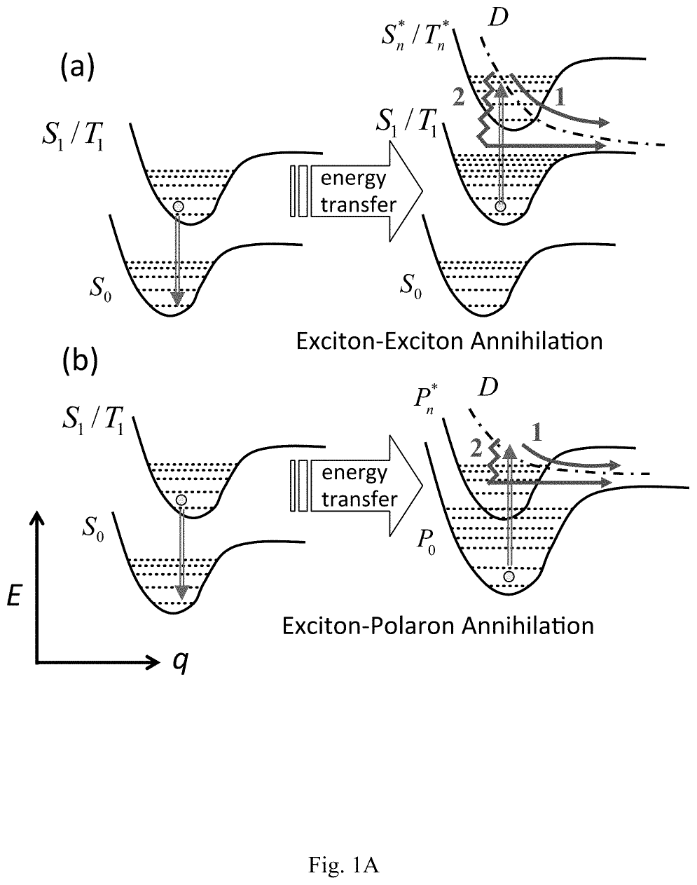

FIG. 1B is a diagram showing various defect generation mechanism and the effect of defects on surrounding excitons and device lifetime.

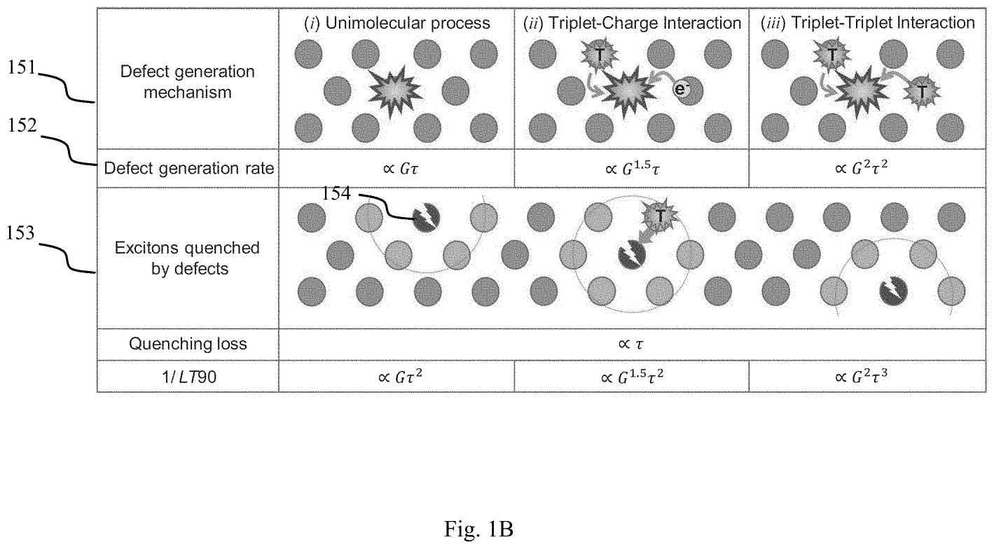

FIG. 2 shows an organic light emitting device;

FIG. 3 shows an inverted organic light emitting device that does not have a separate electron transport layer;

FIG. 4A shows Emission spectra of six different Cu-based TADF emitters with a photoluminescent yield of φ_{PL}→1 with radiative lifetimes of 1.0-1.5 μs;

FIG. 4B shows excited state energy levels under ultrastrong coupling resulting in vibronic decoupling and reduced effect of dark states in the overall photoresponse and the excited state dynamics;

FIG. 5 shows an exemplary architecture of an organic light emitting device;

FIG. 6 shows an exemplary architecture of an organic light emitting device;

FIG. 7A shows an exemplary blue emitting (at 450nm) OLED structure with two metal contacts and two mirrors (one metallic) allowing for optically pumping the device in an ultrastrong coupling regime; and

FIG. 7B shows a photonic density of states versus propagation constant, (β, with the various SPP modes shown at (β>1.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

In the context of organic materials, the terms “donor” and “acceptor” refer to the relative positions of the HOMO and LUMO energy levels of two contacting but different organic materials. This is in contrast to the use of these terms in the inorganic context, where “donor” and “acceptor” may refer to types of dopants that may be used to create inorganic n- and p- types layers, respectively. In the organic context, if the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

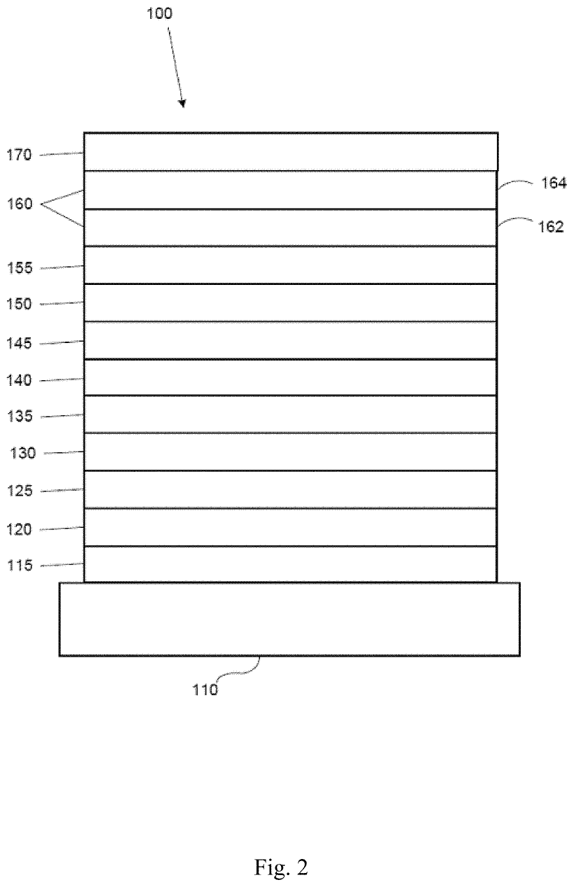

FIG. 2 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

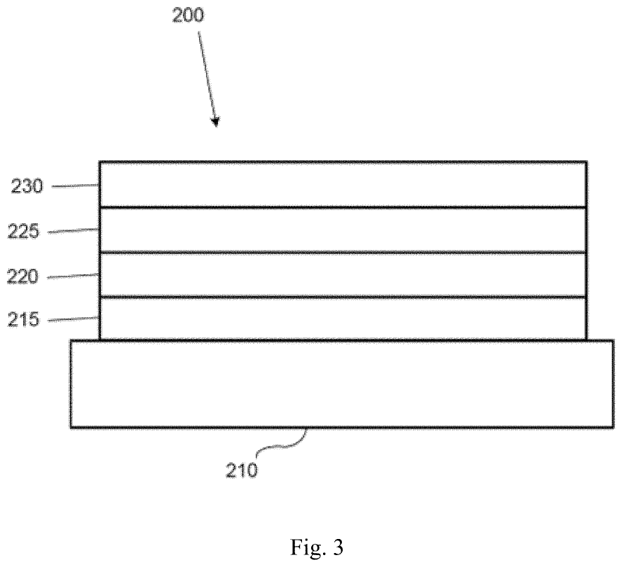

FIG. 3 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 3 provides one example of how some layers may be omitted from the structure of device 100.

The simple layered structure illustrated in FIG. 2 and FIG. 3 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIG. 2 and FIG. 3.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 2 and 3. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present disclosure, including passive matrix and active matrix. Many of the devices are intended for use in a temperature range comfortable to humans, such as 18 C to 30 C, and more preferably at room temperature (20-25 C), but could be used outside this temperature range, for example, from -40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. Application No. 15/700,352, which is hereby incorporated by reference in its entirety), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

In some embodiments, an emissive material as contemplated herein may comprise a donor molecule, an acceptor molecule, and one or more metal atoms linking the donor and acceptor molecules. In one embodiment, at least one donor material and at least one acceptor material form at least one heterojunction. The dissociation of an exciton will typically occur at the “heterojunction” formed by the juxtaposition of donor and acceptor materials. In some embodiments, the heterojunction is chosen from a mixed heterojunction, a bulk heterojunction, a planar heterojunction, a nanocrystalline-bulk heterojunction, and a hybrid planar-mixed heterojunction. The donor and acceptor materials may be deposited by at least one technique chosen from, for example, vacuum deposition, spin coating, organic vapor-phase deposition (OVPD), inkjet printing, and vacuum thermal evaporation (VTE).

The acceptor molecule can be any acceptor molecule known to a person of skill in the art. In one embodiment, the acceptor molecule is a carbene. The carbene can be any carbene known to a person of skill in the art. In one embodiment, the carbene is one the following structures:

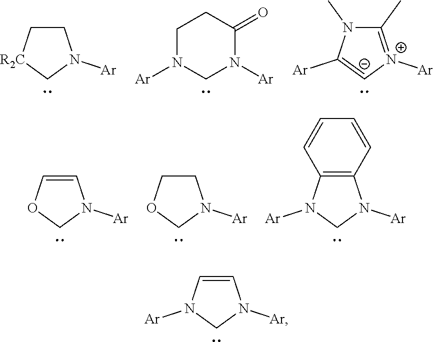

wherein R₂ is an alkyl or aryl group. The aryl groups (Ar) are preferentially substituted in the 2- and 6-positions with alkyl groups, such as methyl, ethyl or isopropyl.

In one embodiment, the acceptor molecule is a carbene having the following structure:

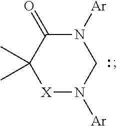

wherein:

X represents CH₂ or C═O; and

each Ar independently represents a phenyl group, preferentially substituted in the 2- and 6-positions with alkyl groups, such as methyl, ethyl or isopropyl. The donor molecule can be any donor molecule known to a person of skill in the art. Suitable donor molecules include, but are not limited to, N-carbazolyl, dialkylamino, diarylamino, N-benzimidazolyl, alkoxide, aryloxide, thioalkyl and thioaryl. In one embodiment, the donor molecule comprises an amide. In one embodiment, the donor molecule comprises an amine. In one embodiment, the donor molecule is carbazole. In one embodiment, the donor molecule is diphenylamine. In one embodiment, the donor molecule is

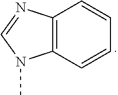

In one embodiment, the donor molecule is an optionally substituted carbazole molecule or diphenylamine molecule. In one embodiment, the optionally substituted carbazole is substituted with one or more CN groups. In one embodiment, the optionally substituted carbazole is substituted with two CN groups.

In one embodiment, the donor molecule and the acceptor molecule are linked through a metal atom. The metal atom can be any metal atom known to a person of skill in the art. In one embodiment, the metal atom is copper, silver, or gold in any oxidation state possible for the particular metal. In one embodiment, the metal atom links a carbene acceptor and an amide donor to form a cMA compound. In one embodiment, the metal atom links a carbene acceptor and an amine donor to form a cMA compound. In one embodiment, the cMA compound is

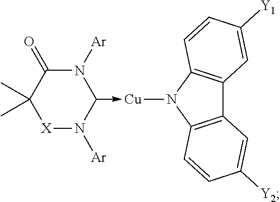

wherein:

“→” represents a bond from the carbene to the metal of the cMa compound;

X represents CH₂ or C═O;

Y₁ and Y₂ each independently represent H or CN; and

each Ar independently represents a phenyl group, preferentially substituted in the 2- and 6-positions with alkyl groups, such as methyl, ethyl or isopropyl.

In some embodiments, a device of the disclosure may include a copper-based material having near unity photoluminescent efficiency, with radiative lifetime in the range of 500 ns to 5 μs, or 1 μs to 3 μs. Additional information about some suitable copper-based materials may be found in Hamze, R., et al., Eliminating nonradiative decay in Cu(I) emitters: >99% quantum efficiency and microsecond lifetime. Science 2019, 363 (6427), 601-606 and Shi, S., et al., Highly Efficient Photo- and Electroluminescence from Two-Coordinate Cu(I) Complexes Featuring Nonconventional N-Heterocyclic Carbenes. J. Am. Chem. Soc. 2019, 141 (8), 3576-3588, both of which are incorporated herein by reference.

In various embodiments, the present disclosure includes light-emitting devices and methods for producing light-emitting devices having a long device operational lifetime (in some embodiments, T70 is at least 50,000 hours, at least 45,000 hours, at least 40,000 hours, or at least 60,000 hours) while also having a high initial luminance (in some embodiments, Lo is at least 3000 cd/m², or at least 4000 cd/m², or at least 2000 cd/m², or at least 2500 cd/m²), and a high external quantum efficiency (EQE in certain embodiments may be at least 12%, at least 15%, at least 18%, at least 20%, at least 22%, or at least 25%). In some embodiments, a device of the disclosure may have 100% or near 100% internal efficiency. Although the described methods and devices may be presented in the context of white OLED emitting devices (referred to herein as WOLED devices), it is understood that the methods and improvements described herein may also be used to produce improved OLED devices of other colors, improved OLED displays, or any other suitable devices.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

The connection between the radiative lifetime to exciton annihilation can be understood as follows. The probability of encounter of an exciton and polaron that leads to molecular dissociation is

$${P}_{T P A} = \frac{3 {K}_{x}}{{k}_{r} 4 π {r}^{3}} \qquad Equation 2$$

where kᵣ is the radiative rate of the emitting species, Kₓ is the rate of defect formation (˜10²³ cm³/s for many blue phosphors, and r is the exciton encounter radius (approximately equal to the molecular diameter). Thus, a reduction in molecular radiative rate leads to an increase in OLED lifetime by approximately the same amount. While Equation 2 is valid for TPA, if molecular degradation occurs primarily via TTA, then the probability is defined as

$${P}_{T T A} \approx \frac{1}{{k}_{r}^{2}}$$

in which case the enhancement in lifetime increases much more rapidly. The dominance of TPA or TTA for a given materials system is determined by analysis of the transient response of the OLED. Because the polariton lifetime is governed by the cavity quality factor (and hence the polariton lifetime), it can be orders of magnitude shorter than the natural excited state lifetime, making the probability for molecular damage also decrease by several orders of magnitude.

As referred to herein, the quality factor (also referred to as the Q factor) of a given cavity is a dimensionless property of a resonant cavity given by the equation

$$Q = \frac{2 π {v}_{0} {T}_{rt}}{l}$$

Where v₀ is the optical frequency, l is the fractional power loss per round trip, and Tᵣₜ is the round-trip time.

There have been early demonstrations of using surface plasmon polariton coupling to decrease the emission lifetime in OLEDs. In one exemplary work, random distributions of metallic nanoparticles were distributed onto the anode surface. While this was a proof of concept that resulted in an approximately two times longer OLED lifetime, the coupling in that case remained weak and uncontrolled. In this thrust, the polariton emission can reduce the radiative lifetime by several orders of magnitude—a situation that is unapproachable using non-resonant cavities comprising nanoparticle distributions.

In the present disclosure, short triplet emitter operational lifetimes are extended by combining the development of a new class of blue emitters with manipulation of their radiative lifetimes via strong coupling. Microcavities filled with blue TADF emitters are used in a strong coupling regime. This lends the nearly degenerate singlet-triplet state to gain significant photonic character. In some embodiments, strong coupling reduces the lifetimes of TADF emitters from 0.5-2 μs to that of the polariton lifetime of under hundreds of picoseconds. So-called “coinage metal” (Cu, Ag, Au) based TADF emitters are used to increase blue emission stability via strong coupling. More information and additional embodiments of emissive devices with reduced radiative lifetimes may be found in U.S. patent application Ser. No. 16/925,777, incorporated herein by reference in its entirety.

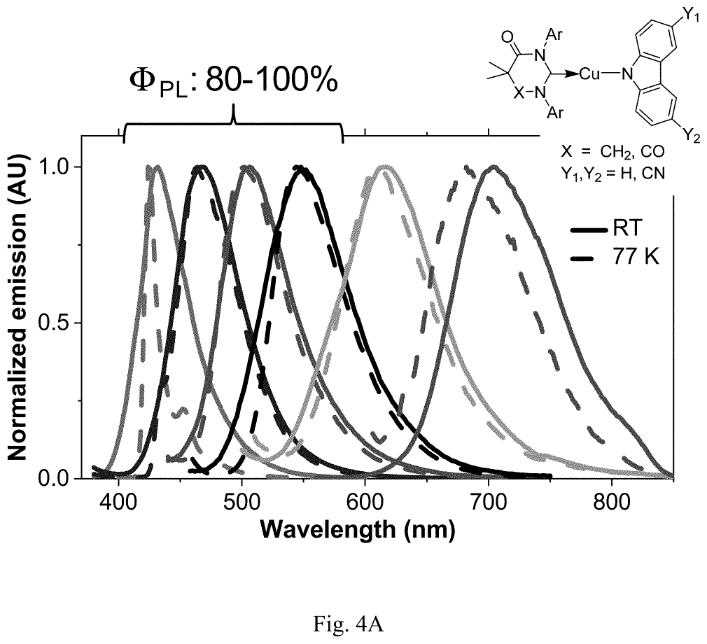

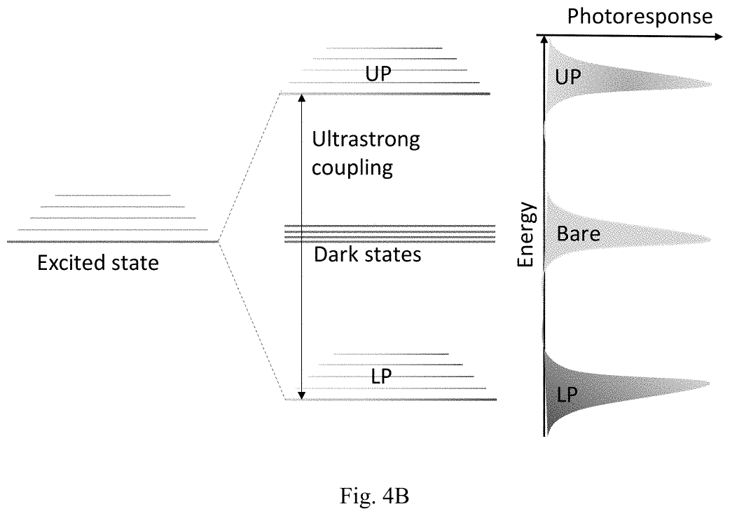

For example, copper-based TADF materials can be modified to emit throughout the visible spectrum, giving near unity photoluminescent efficiency, with lifetimes in the 1-3 μs range (see FIG. 4A). These materials have been used to prepare blue and green emissive OLEDs with high efficiencies (ca. EQE=20%). It has also found that the Ag- and Au-based analogs of these materials give high luminance efficiencies with radiative lifetimes as short as 0.5 μs. Incorporating TADF emitters into microcavities therefore reduces the radiative lifetime, in some embodiments to the order of hundreds of nanoseconds via the Purcell effect, thus increasing the stability of those emissive materials accordingly.

One issue that must be faced in the disclosed devices is the stability of the molecules themselves. Particularly, Ag-based TADF molecules have a weak coordinating bond with the ligands, leading to intrinsically low stabilities. In some embodiments, Cu-based molecules are used which exhibit much better stability.

One of the major challenges to modify excited state dynamics using strong coupling is the presence of dark states and the exciton reservoir states as discussed above (see FIG. 4B). With reference to FIG. 4B, Excited state energy levels under ultrastrong coupling resulting in vibronic decoupling and reduced effect of dark states in the overall photoresponse and the excited state dynamics. Despite the polaritons themselves having short lifetimes coming from their cavity lifetime, it has been shown that the lifetimes of the hybrid states can be longer than their cavity limited lifetimes. In previous work, ultrafast spectroscopy was used to demonstrate the long lifetime of polaritons inherited from the dark states. In these demonstrations, the cavity operated in the strong coupling regime where there was overlap between the energies of the dark states and the lower polaritons. In contrast as shown in FIG. 4B, under ultrastrong coupling, the overlap between the dark states and the lower polariton states are minimal, and in this case direct injection/pumping into the lower polariton branch allows one to significantly modify the polariton state dynamics and leverage the hybrid nature of these states. Indeed, recent polariton LED work from Menon in the context of 2D materials as well as from the Kena-Cohen group on organic materials showed the overall enhancement in lower polariton emission.

Optimizing device geometry to achieve efficient injection into the lower polariton branch is a key aspect of some embodiments of the disclosure.

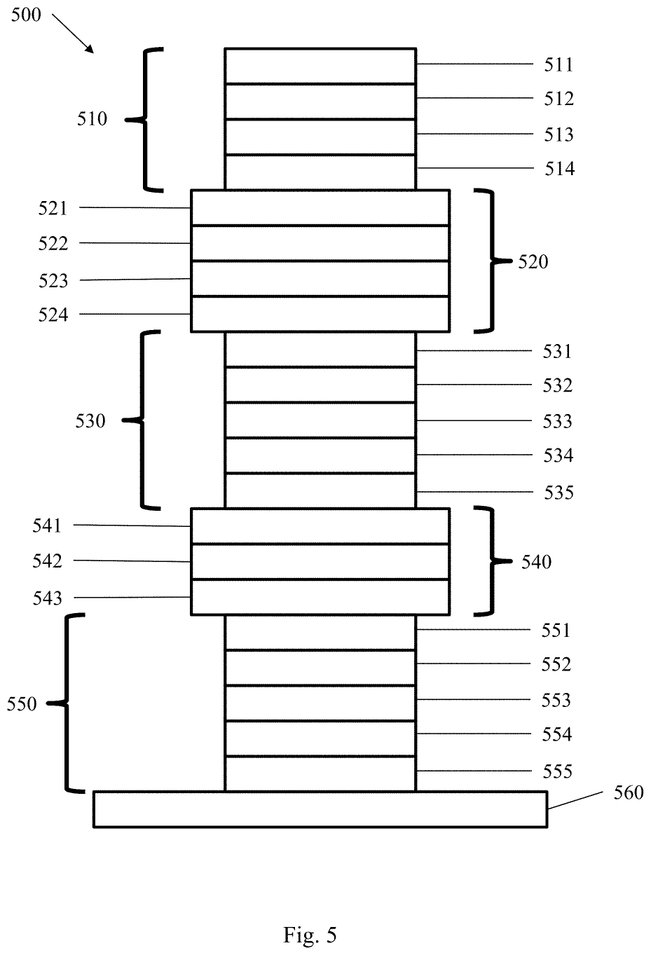

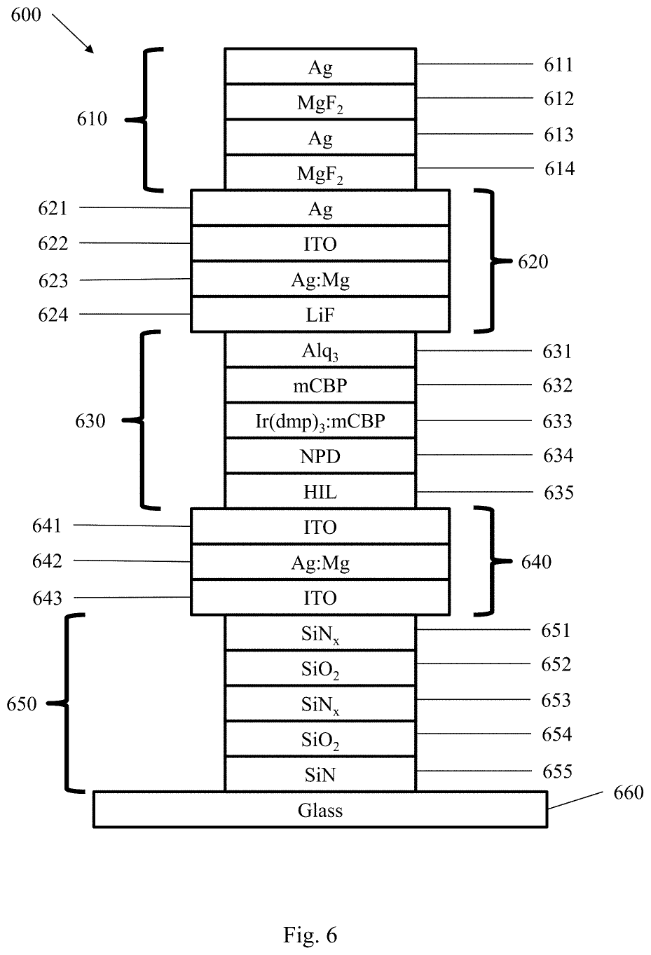

To achieve the ultrastrong coupling regime, various cavities as disclosed herein may be implemented. In some embodiments, a cavity may comprise a top and/or a bottom reflector, where a reflector may comprise one or more of a contact, a layer stack comprising one or more sublayers, each comprising one or more materials, a metal mirror, a distributed Bragg reflector (DBR) or the like. One exemplary device architecture is shown in FIG. 5, with one exemplary OLED structure of the device architecture shown in FIG. 6.

With reference to FIG. 5, the device 500 may be presented in a cross-sectional view as shown, with a plurality of layers disposed in a stack. The depicted layer stack may further be defined as a set of sub-stacks, layers, or cross-sectional regions of the device presented in braces, namely 510, 520, 530, 540, and 550. The optional substrate 560 on which the layer stack is deposited may be any suitable material, and may in some embodiments be a transparent substrate, for example comprising glass.

In some embodiments, the depicted layer stack comprises one or more electrodes or electrode regions, for example one anode and one cathode. In one embodiment, the region 510 and/or the region 520 may be a cathode, and the region 540 may be an anode. In one embodiment, the region 520 is the cathode. The electrodes or electrode regions may comprise one or more sublayers, for example conductive or semiconductor sublayers. In one embodiment, a cathode may comprise Ag or Ag:Mg, in some embodiments, one or more of the anode and the cathode may comprise ITO. In some embodiments, one or more of the anode and the cathode may comprise LiF. In some embodiments, a total thickness of a cathode may be less than 100 nm, less than 80 nm, or less than 50 nm. In some embodiments, a total thickness of an anode may be less than 100 nm, less than 80 nm, or less than 50 nm. In some embodiments, one or more of the anode and the cathode may comprise alternating sublayers comprising Ag and ITO. In some embodiments, a cathode may comprise a LiF layer at a surface closest to the emissive region.

In some embodiments, a layer stack may comprise top and bottom reflector regions, 510 and 550, respectively. In some embodiments, the top and bottom reflectors may comprise metal sublayers, and in other embodiments, the top and/or the bottom reflector may not comprise metal sublayers, and may instead comprise SiO₂, SiNₓ, Al₂O₃, MgF₂, TiO₃, In₂O₃. In some embodiments, the top or bottom reflector region 510 or 550 may have a total thickness of between 10 nm and 1 um, or between 50 nm and 500 nm, or between 100 nm and 400 nm, or between 200 nm and 300 nm, or between 300 nm and 400 nm, or between 200 nm and 400 nm.

In some embodiments, one or more electrode regions 520 and 550 may be formed at a specific thickness in order to adjust a distance between a corresponding reflector region and one or more of the emissive layers in the emissive region 530. For example, in one embodiment, an anode region 540 and/or part or all of an emissive region 530 may be thinner in order to bring an emissive layer 533 closer to an anode side reflector 550. In one embodiment, an anode region 540, a cathode region 520, and/or an emissive region 530 may be configured to be thicker or thinner in order to change the distance between an emissive layer 533 and one or both reflector regions forming a cavity.

In some embodiments, a reflector 510 or 550 may comprise sublayers comprising materials including but not limited to MgF₂, Ag, Ag:Mg, Al, Pt, Pd, Au, SiNₓ, SiO₂, Al₂O₃, AlOₓ, MgF₂, TiO₃, or In₂O₃. In some embodiments, a reflector may comprise a repeating sequence of sublayers comprising two or more of the materials as disclosed herein.

In some embodiments, one or both of the reflectors may be a distributed Bragg reflector (DBR) and/or an outcoupling reflector configured to outcouple at least part of the energy, for example via a transparent substrate 560.

In some embodiments, an emissive region 530 may be positioned between the electrodes 520 and 540. The emissive region may comprise one or more emissive layers and may additionally comprise one or more charge transport layers. In some embodiments, an emissive region 530 may comprise a blue emitter, a green emitter, a red emitter, combinations of these, or a white emitter. In some embodiments, the emissive region may comprise a host material and/or a host layer. In some embodiments, an emissive region may comprise one or more layers comprising materials selected from Alq₃, Ir(dmp)₃, mCBP, NPD, TADF emitters, fluorescent emitters, BCM, BCM2, Coumarin 543, or other Iridium complexes. In some embodiments, an emissive region may comprise one or more charge transport layers or sublayers, for example a hole transport layer, or an electron transport layer. In some embodiments, an emissive region may have a total thickness of less than 500 nm, less than 400 nm, less than 300 nm, less than 200 nm, 100 nm, less than 90 nm, less than 80 nm, less than 70 nm, less than 50 nm, or less than 30 nm.

One specific exemplary embodiment of the device 500 is shown in FIG. 6. The exemplary device comprises a glass substrate 660, onto which is disposed an anode-side DBR reflector with outcoupling compensation 650, which comprises alternating sublayers of SiNₓ (651, 653, and 655) and SiOₓ (652, 654). In the depicted embodiment, each sublayer 651-655 in region 650 has a thickness of between 40 nm and 100 nm, and in one embodiment, each sublayer of SiNₓ has a thickness of about 56 nm, and each sublayer of SiO₂ has a thickness of about 80 nm.

In the depicted embodiment, the anode region 640 comprises outer ITO layers 641 and 643 on either side of a metal layer 642, which may in some embodiments comprise Ag or Ag:Mg. In one embodiment, one or both of the ITO layers has a thickness of between 10 nm and 20 nm, or about 15 nm. In one embodiment the metal layer 642 has a thickness of between 10 nm and 20 nm, or about 16 nm.

In the depicted embodiment, the emissive region 630 comprises a hole injection layer 635, which may be a thin hole injection layer, for example having a thickness of less than 10 nm, or about 5 nm. The emissive region 630 may further comprise a hole transport layer 634, which may in some embodiments comprise NPD. The hole transport layer 634 may in some embodiments have a thickness of between 10 nm and 20 nm, or about 15 nm. In some embodiments, the emissive region 630 comprises an emitter, which may span one or more sublayers and comprise sublayers having a host and an emissive material, only an emissive material, or only a host material. In the depicted embodiment, emissive layer 633 comprises a blue emissive material Ir(dmp)₃ combined with a host material, mCBP. The depicted embodiment further comprises a layer of only host material mCBP positioned between the cathode region 620 and the emissive layer 633. The emissive layer may in some embodiments have a thickness of less than 500 nm, less than 400 nm, less than 300 nm, less than 200 nm, less than 100 nm, less than 80 nm, or less than 50 nm. In some embodiments, the emissive layer may comprise a volumetric ratio of emissive material to host material of 10:90, 20:80, 30:70, 40:60, or 50:50. In some embodiments, the emissive layer may comprise one or more sublayers of host material surrounding a sublayer of a pure emissive material. In some embodiments, a sublayer of pure emissive material may be a monolayer, or have a thickness of between 1 monolayer and 20 nm.

In the depicted embodiment, the emissive region 630 further comprises an electron transport layer 631 positioned between the emissive layer 633 and the cathode region 620. The depicted electron transport layer comprises Alq₃, and may further have a thickness of between 10 nm and 20 nm, or about 14 nm.

The depicted device 600 further comprises a cathode region 620, comprising alternating conductive layers of Ag (621) ITO (622) and Ag:Mg (623). In some embodiments, one or more of the metal layers in the cathode region 620 may be thin metal layers, for example having a thickness of less than 100 nm, less than 90 nm, less than 80 nm, less than 70 nm, less than 60 nm, less than 50 nm, less than 40 nm, less than 30 nm, less than 20 nm, less than 10 nm, or about 5 nm. In the depicted embodiment, the cathode region 620 further comprises an insulating layer 624, which in the depicted embodiment comprises LiF.

The depicted device 600 further comprises a cathode-side reflector region 610, which in the depicted embodiment comprises alternating layers of Ag and MgF₂. In some embodiments, the cathode sublayers 611-614 each have a thickness of less than 50 nm, less than 40 nm, less than 30 nm, less than 20 nm, or less than 10 nm. In some embodiments, one or more of the cathode region and the anode region may be opaque, or semi-transparent.

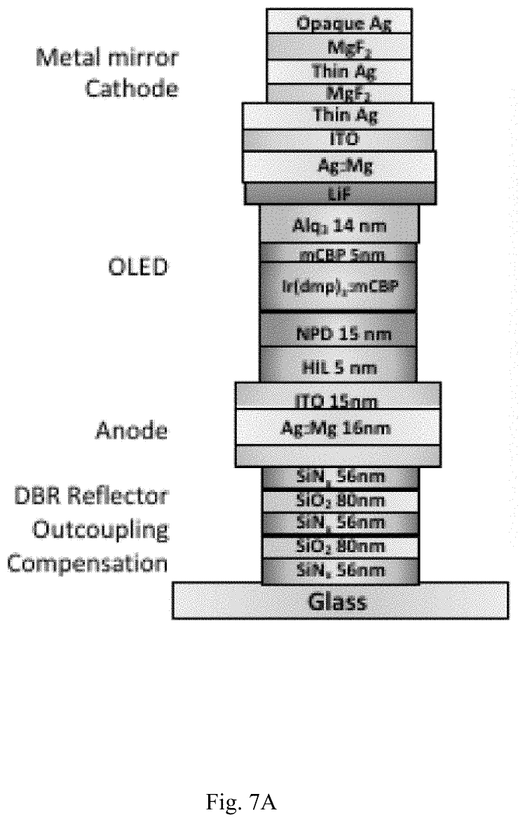

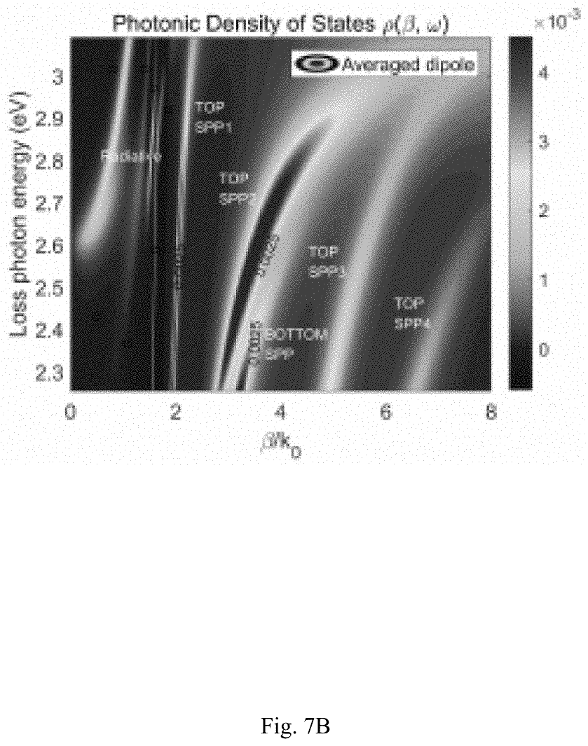

In some embodiments, cavities created by the reflector regions in devices disclosed herein provide smaller mode volume and may have a hybrid cavity design which has a bottom DBR and a top metal mirror such as those shown by Menon to optimize both mode volume and cavity quality factor. In some embodiments, one or both reflectors comprise a metal, while in other embodiments, one or both reflectors comprise a semiconductor. A schematic of the proposed device geometry is shown in FIG. 7A (and more generally in FIG. 6) along with the dispersion (FIG. 7B). Here the crucial step is in the design of the injection scheme for efficient electrical polariton injection, requiring the use of particular materials in the mirror/reflector regions 610 and 650, and in the electrode regions 620 and 640. These same reflectors are demonstrated as a simple means to achieve ultrastrong coupling. In some disclosed embodiments, polariton OLEDs show significantly reduced radiative lifetime from hundreds of nanoseconds to tens of picoseconds depending on the cavity quality factor and the overlap of the energies with the dark states. This vastly reduces TTA and TPA destructive interactions thereby increasing the radiative efficiency according to Equation 1, narrows the spectral width to allow for saturated, deep blue emission, and increases the emission stability to tens of thousands of hours, finally resolving the decades-old problem of low stability of blue triplet emitters.

In some embodiments disclosed herein, the emitting zone is positioned in a resonant, electrically pumped cavity. In some embodiments, the emitting molecule has a high absorption oscillator strength. TADF molecules may be used in some embodiments, because TADF molecules can absorb strongly into S1. The lower singlet-triplet splitting leading to high efficiency TADF emission, however, depletes its oscillator strength, which is shared between Si and the T1 reservoir states. Hence, in some embodiments, TADF molecules are used with S-T splitting of less than 100 meV, less than 90 meV, less than 80 meV, less than 70 meV, less than 60 meV, less than 50 meV, less than 40 meV, less than 30 meV, or less than 20 meV. In some embodiments, coinage metal molecules are used such as those in FIG. 4. In some embodiments, the cavity stop band is configured to encompass both S1 and T1 to allow for efficient coupling of both the singlet and triplet excitonic states with the cavity photons. In some embodiments, the cavity is configured to allow ultrastrong coupling through its quality factor. In some embodiments, a cavity as disclosed herein may be configured to have a quality factor of at least 5, at least 6, at least 7, at least 8, at least 9, at least 10, at least 50, at least 100, at least 200, at least 500, or at least 1000. Configuring a cavity in a device with a high quality factor ensures that uncoupled, dark states as discussed above do not mix with the lower branch polaritons. If this were the case, the long exciton lifetime would remove the advantage gained by ultrashort lifetime polaritonic states, and thus stability would not improve. In some embodiments, a device is configured to directly electrically pump the LP states, which is made possible through ultrastrong coupled cavities where the dark and LP state degeneracy is lifted.

In some embodiments, one or more reflectors of a cavity of a disclosed device may be configured such that the photon and exciton energies of the cavity are in resonance, and the cavity loaded with the emissive material has a high quality factor as disclosed herein. The mirrors can be comprised of dielectric stacks, or metals or combinations of a dielectric stack and a metal mirror on opposing sides of the emissive layer supporting the excitonic state. The emissive material may in some embodiments reside wholly or partially at the peak of the optical field between the opposing mirrors which in some embodiments is approximately at a distance of one quarter of a wavelength within the cavity. (λ/4n where n is the real part of the refractive index of the emissive material.) In various embodiments, the peak may be positioned at a distance of one quarter of a wavelength from one reflector, or from both reflectors. Dielectric stacks may in some embodiments comprise at least 2 materials, for example alternating layers of two or more materials, (including but not limited to the families SiO₂, SiN_{X}, Al₂O₃, MgF₂, TiO₃, In₂O₃) whose indexes of refraction differ by at least 0.05. In some embodiments, the cavity may be configured such that plasma resonance is not within the resonant frequency of the cavity.

The use of ultrastrong coupled, electrically pumped OLEDs to reduce excited state lifetimes and enhance stability is a novel approach to improving the stability of blue emitters. With the disclosed devices and methods, blue OLEDs will no longer be the “weak point” in the reliability of displays and lighting. Electrically pumped organic polaritonic lasers with long term stability may be realized. The disclosed cavity approach may revolutionize the ability to exploit and study organic emission at very high energies and over long time periods that have not yet been possible due to the frailty of organic bonds and the high excitation densities exploited in most devices, such as light emitters, solar cells and transistors.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

The following publications are incorporated herein by reference in their entirety:

Samuel, I. D. W. & Turnbull, G. A. Organic semiconductor lasers. Chemical Reviews vol. 107 1272-1295 (2007).

Kéna-Cohen, S. & Forrest, S. R. Room-temperature polariton lasing in an organic single-crystal microcavity. Nat. Photonics 4, 371-375 (2010).

Fontcuberta i Morral, A. & Stellacci, F. Light-matter interactions: Ultrastrong routes to new chemistry. Nat. Mater. 11, 272-273 (2012).

Hutchison, J. A., Schwartz, T., Genet, C., Devaux, E. & Ebbesen, T. W. Modifying Chemical Landscapes by Coupling to Vacuum Fields. Angew. Chemie Int. Ed. 51, 1592-1596 (2012).

Yuen-Zhou, J. & Menon, V. M. Polariton chemistry: Thinking inside the (photon) box. Proc. Natl. Acad. Sci. U. S. A. 201900795 (2019) doi:10.1073/pnas.1900795116.

Ribeiro, R., Martinez-Martinez, L., Du, M., Campos-Gonzalez-Angulo, J. & Yuen-Zhou, J. Polariton chemistry: Controlling molecular dynamics with optical cavities. Chem Sci 9, 6325-6339.

Coles, D. M. et al. Polariton-mediated energy transfer between organic dyes in a strongly coupled optical microcavity. Nat. Mater. 13, 712-719 (2014).

Hou, S. et al. Ultralong-Range Energy Transport in a Disordered Organic Semiconductor at Room Temperature Via Coherent Exciton-Polariton Propagation. Adv. Mater. 32, 2002127 (2020).

Sanvitto, D. & Kéna-Cohen, S. The road towards polaritonic devices. Nat. Mater. 15, 1061-1073 (2016).

Maser, A., Gmeiner, B., Utikal, T., Gotzinger, S. & Sandoghdar, V. Few-photon coherent nonlinear optics with a single molecule. Nat. Photonics 10, 450-453 (2016).

Chikkaraddy, R. et al. Single-molecule strong coupling at room temperature in plasmonic nanocavities. Nature 535,127-130 (2016).

Thomas, A. et al. Ground-State Chemical Reactivity under Vibrational Coupling to the Vacuum Electromagnetic Field. Angew. Chemie Int. Ed. 55,11462-11466 (2016).

Zhong, X. et al. Energy Transfer between Spatially Separated Entangled Molecules. Angew. Chemie Int. Ed. 56,9034-9038 (2017).

Kéna-Cohen, S., Maier, S. A. & Bradley, D. D. C. Ultrastrongly Coupled Exciton-Polaritons in Metal-Clad Organic Semiconductor Microcavities. Adv. Opt. Mater. 1,827-833 (2013).

George, J. et al. Multiple Rabi Splittings under Ultrastrong Vibrational Coupling. Phys. Rev. Lett. 117,153601 (2016).

Frisk Kockum, A., Miranowicz, A., De Liberato, S., Savasta, S. & Nori, F. Ultrastrong coupling between light and matter. Nat. Rev. Phys. 1,19-40 (2019).

Ribeiro, R. F., Martinez-Martinez, L. A., Du, M., Campos-Gonzalez-Angulo, J. & Yuen-Zhou, J. Polariton chemistry: controlling molecular dynamics with optical cavities. Chem. Sci. 9, 6325-6339 (2018).

Liu, B., Menon, V. M. & Sfeir, M. Y. The Role of Long-Lived Excitons in the Dynamics of Strongly Coupled Molecular Polaritons. ACS Photonics 7,2292-2301 (2020).

Eizner, E., Martinez-Martinez, L. A., Yuen-Zhou, J. & Kéna-Cohen, S. Inverting singlet and triplet excited states using strong light-matter coupling. Sci. Adv. 5, eaax4482 (2019).

Hou, S. et al. Ultralong-Range Energy Transport in a Disordered Organic Semiconductor at Room Temperature Via Coherent Exciton-Polariton Propagation. Adv. Mater. 2002127 (2020) doi:10.1002/adma.202002127.

Gonzalez-Ballestero, C., Feist, J., Gonzalo Badia, E., Moreno, E. & Garcia-Vidal, F. J. Uncoupled Dark States Can Inherit Polaritonic Properties. Phys. Rev. Lett. 117, 156402 (2016).

Liu, B., Menon, V. M. & Sfeir, M. Y. The Role of Long-lived Excitons in the Dynamics of Strongly Coupled Molecular Polaritons. ACS Photonics acsphotonics.0c00895 (2020) doi:10.1021/acsphotonics.0c00895.

Gu, J., Chakraborty, B., Khatoniar, M. & Menon, V. M. A room-temperature polariton light-emitting diode based on monolayer WS2. Nature Nanotechnology (2019) doi:10.1038/s41565-019-0543-6.

Gubbin, C. R., Maier, S. A. & Kéna-Cohen, S. Low-voltage polariton electroluminescence from an ultrastrongly coupled organic light-emitting diode. Appl. Phys. Lett. 104, 233302 (2014).

Kéna-Cohen, S. & Maier, S. Ultrastrongly Coupled Exciton-Polaritons in Metal-Clad Organic Semiconductor Microcavities. Adv. Opt. (2013).

Thomas, A. et al. Tilting a ground-state reactivity landscape by vibrational strong coupling. Science (80-.). 363, 615-619 (2019).

Thomas, A. et al. Tilting a ground-state reactivity landscape by vibrational strong coupling. Science (80-.). 363, 615-619 (2019).

Vergauwe, R. M. A. et al. Modification of Enzyme Activity by Vibrational Strong Coupling of Water. Angew. Chemie Int. Ed. 58, 15324-15328 (2019).

Ebbesen, T. W. Hybrid Light-Matter States in a Molecular and Material Science Perspective. Acc. Chem. Res. 49, 2403-2412 (2016).

Campos-Gonzalez-Angulo, J. A., Ribeiro, R. F. & Yuen-Zhou, J. Resonant catalysis of thermally activated chemical reactions with vibrational polaritons. Nat. Commun. 10, (2019).

del Pino, J Garcia-Vidal, F. J. & Feist, J. Exploiting Vibrational Strong Coupling to Make an Optical Parametric Oscillator Out of a Raman Laser. Phys. Rev. Lett. 117, 277401 (2016).

Pang, Y. et al. On the Role of Symmetry in Vibrational Strong Coupling: The Case of Charge-Transfer Complexation. Angew. Chemie Int. Ed. 59, 10436-10440 (2020).

Mukamel, S. Principles of Nonlinear Optical Spectroscopy, Oxford University Press, New York. Principles of Nonlinear Optical Spectroscopy, Oxford University Press, New York (1995).

Hamm, P. Principles of Nonlinear Optical Spectroscopy: A Practical Approach. (2005).

DelPo, C. A. et al. Polariton Transitions in Femtosecond Transient Absorption Studies of Ultrastrong Light-Molecule Coupling. J. Phys. Chem. Lett. 11, 2667-2674 (2020).

Ramezani, M., Halpin, A., Wang, S., Berghuis, M. & Rivas, J. G. Ultrafast Dynamics of Nonequilibrium Organic Exciton-Polariton Condensates. Nano Lett. 19, 8590-8596 (2019).

Yamashita, K. et al. Ultrafast Dynamics of Polariton Cooling and Renormalization in an Organic Single-Crystal Microcavity under Nonresonant Pumping. ACS Photonics 5, 2182-2188 (2018).

Sanvitto, D. & Kéna-Cohen, S. The road towards polaritonic devices. Nat. Publ. Gr. 15, (2016).

Herrera, F. & Spano, F. C. Cavity-Controlled Chemistry in Molecular Ensembles. Phys. Rev. Lett. 116, (2016).

Polak, D. et al. Manipulating molecules with strong coupling: Harvesting triplet excitons in organic exciton microcavities. Chem. Sci. 11, 343-354 (2020).

Feist, J., Galego, J. & Garcia-Vidal, F. J. Polaritonic Chemistry with Organic Molecules. ACS Photonics 5, 205-216 (2018).

Berghuis, A. M. et al. Strong Light-Matter Coupling: Enhanced Delayed Fluorescence in Tetracene Crystals by Strong Light-Matter Coupling (Adv. Funct. Mater. 36/2019). Adv. Funct. Mater. 29, 1970249 (2019).

Martinez-Martinez, L. A., Du, M., Ribeiro, R. F., Kéna-Cohen, S. & Yuen-Zhou, J. Polariton-Assisted Singlet Fission in Acene Aggregates. J. Phys. Chem. Lett. 9, 1951-1957 (2018).

Kretschmann, E. & Raether, H. Notizen: Radiative Decay of Non Radiative Surface Plasmons Excited by Light. Zeitschrift für Naturforsch. A 23, 2135-2136 (1968).

Lieb, M. A., Zavislan, J. M. & Novotny, L. Single-molecule orientations determined by direct emission pattern imaging. J. Opt. Soc. Am. B 21, 1210 (2004).

Kanal, F., Keiber, S., Eck, R. & Brixner, T. 100-kHz shot-to-shot broadband data acquisition for high-repetition-rate pump—probe spectroscopy. Opt. Express 22, 16965 (2014).

Kearns, N. M., Mehlenbacher, R. D., Jones, A. C. & Zanni, M. T. Broadband 2D electronic spectrometer using white light and pulse shaping: noise and signal evaluation at 1 and 100 kHz. Opt. Express 25, 7869 (2017).

Delor, M., Weaver, H. L., Yu, Q. & Ginsberg, N. S. Imaging material functionality through three-dimensional nanoscale tracking of energy flow. Nat. Mater. 19, 56-62 (2020).

Brazard, J., Bizimana, L. A. & Turner, D. B. Accurate convergence of transient-absorption spectra using pulsed lasers. Rev. Sci. Instrum. 86, 053106 (2015).

Smallwood, C. L., Jozwiak, C. & Lanzara, A. An ultrafast angle-resolved photoemission apparatus for measuring complex materials. Rev. Sci. Instrum. 83, 123904 (2012).

Bovensiepen, U. & Kirchmann, P. S. Elementary relaxation processes investigated by femtosecond photoelectron spectroscopy of two-dimensional materials. Laser Photon. Rev. 6, 589-606 (2012).

Vasista, A. B., Sharma, D. K. & Kumar, G. V. P. Fourier Plane Optical Microscopy and 5 Spectroscopy. in digital Encyclopedia of Applied Physics 1-14 (Wiley-VCH Verlag GmbH & Co. KGaA, 2019). doi:10.1002/3527600434.eap817.

Schuller, J. a et al. Orientation of luminescent excitons in layered nanomaterials. Nat. Nanotechnol. 8, 271-6 (2013).

Su, R. et al. Observation of exciton polariton condensation in a perovskite lattice at room temperature. Nat. Phys. 16, 301-306 (2020).

Klaas, M. et al. Photon-Number-Resolved Measurement of an Exciton-Polariton Condensate. Phys. Rev. Lett. 121, 047401 (2018).

Vurgaftman, I., Simpkins, B. S., Dunkelberger, A. D. & Owrutsky, J. C. Negligible Effect of Vibrational Polaritons on Chemical Reaction Rates via the Density of States Pathway. J. Phys. Chem. Lett. 11, 3557-3562 (2020).

Liu, B., Menon, V. M. & Sfeir, M. Y. Ultrafast Thermal Modification of Strong Coupling in an Organic Microcavity. (2020).

Dunkelberger, A. D., Spann, B. T., Fears, K. P., Simpkins, B. S. & Owrutsky, J. C. Modified relaxation dynamics and coherent energy exchange in coupled vibration-cavity polaritons. Nat. Commun. 7, 13504 (2016).

Schwartz, T. et al. Polariton Dynamics under Strong Light-Molecule Coupling. ChemPhysChem 14, 125-131 (2013).

Hamm, P. & Zanni, M. Concepts and Methods of 2D Infrared Spectroscopy. (Cambridge University Press, 2011). doi:10.1017/CBO9780511675935.

Skolnick, M. S., Fisher, T. a & Whittaker, D. M. Strong coupling phenomena in quantum microcavity structures. Semicond. Sci. Technol. 13, 645-669 (1998).

What is claimed is:

1. An organic light emitting device, comprising:
an emissive layer stack having an anode side and a cathode side, comprising at least one emissive layer comprising an organic emissive material;
an anode layer stack positioned on the anode side of the emissive layer stack, comprising at least one conductive layer;
a cathode layer stack positioned on the cathode side of the emissive layer stack from the anode layer stack, comprising at least one conductive layer;
an anode-side reflector positioned on the anode side of the emissive layer stack; and
a cathode-side reflector positioned on the cathode side of the emissive layer stack;
wherein the anode-side reflector and the cathode side reflector are configured to form a resonant, electrically pumped cavity for ultrastrong coupling having a quality factor of at least 10.

2. The organic light emitting device of claim 1, wherein the emissive layer comprises a blue organic emissive material.

3. The organic light emitting device of claim 1, wherein the emissive layer stack comprises at least one layer comprising an organic emissive material and a host material, and at least one additional layer comprising a host material.

4. The organic light emitting device of claim 1, wherein the anode-side reflector is a distributed Bragg reflector (DBR)

5. The organic light emitting device of claim 4, wherein the anode-side reflector comprises at least one layer of SiO₂ and at least one layer of SiNₓ

6. The organic light emitting device of claim 1, wherein the cathode-side reflector comprises a metal.

7. The organic light emitting device of claim 1, wherein the cathode-side reflector and the anode side reflector comprise semiconductor materials.

8. The organic light emitting device of claim 1, wherein the cathode side reflector comprises at least one layer of Ag and at least one layer of MgF₂.

9. The organic light emitting device of claim 1, wherein the emissive layer stack comprises at least an electron transport layer and a hole transport layer.

10. The organic light emitting device of claim 1, wherein the cathode layer stack comprises at least one insulating layer.

11. The organic light emitting device of claim 1, wherein the cathode layer stack comprises at least one layer of Indium Tin Oxide.

12. The organic light emitting device of claim 1, wherein the anode layer stack comprises at least one layer of Indium Tin Oxide.

13. An electrically-pumped organic light emitting device, comprising:
a resonant, electrically pumped cavity for ultrastrong coupling formed of first and second reflectors;
an organic emissive layer having a peak emission wavelength λ and positioned in the resonant, electrically pumped cavity between the first and second reflectors, at a distance from the first reflector of about λ/4;
an anode layer stack positioned between the first reflector and the emissive layer; and
a cathode layer stack positioned between the second reflector and the emissive layer;
wherein the electrically pumped cavity is configured to have a quality factor of at least 10.

14. The light emitting device of claim 13, wherein the organic emissive layer comprises an organic emissive material and an organic host material.

15. The light emitting device of claim 14, wherein the organic emissive material is a blue organic emissive material.

16. The light emitting device of claim 13, wherein at least one of the first and second reflectors is a distributed Bragg reflector.

17. The light emitting device of claim 13, wherein the first and second reflectors each comprise a plurality of semiconducting sublayers.

18. The light emitting device of claim 17, wherein the first and second reflectors do not comprise a metal sublayer.

19. The light emitting device of claim 13, further comprising an insulating layer positioned between the cathode layer stack and the emissive layer.

20. The light emitting device of claim 13, further comprising a hole injection layer positioned between the anode layer stack and the emissive layer.
